(19) United States
(12) Patent Application Publication
(10) Pub. No.: US 2011/0316161 A1
(43) Pub. Date: Dec. 29, 2011

(54) METHOD OF PRODUCING A DUAL DAMASCENE MULTILAYER INTERCONNECTION AND MULTILAYER INTERCONNECTION STRUCTURE

(75) Inventors: Hiroto OHTAKE, Kanagawa (JP); Munehiro TADA, Kanagawa (JP); Makoto UEKI, Kanagawa (JP); Yoshihiro HAYASHI, Kanagawa (JP)

(73) Assignee: RENESAS ELECTRONICS CORPORATION, Kanagawa (JP)

(21) Appl. No.: 13/227,031

(22) Filed: Sep. 7, 2011

Related U.S. Application Data
(62) Division of application No. 12/160,149, filed on Jul. 7, 2008.

(30) Foreign Application Priority Data
Jan. 6, 2006 (JP) 2006-001864

(51) Int. Cl. H01L 23/522; H01L 21/768

(52) U.S. Cl. 257/758; 438/637; 257/E21.577; 257/E21.579; 257/E23.145

(57) ABSTRACT

In an insulating film structure having a barrier insulating film, a via interlayer insulating film, a wiring interlayer insulating film, and a hard mask film stacked in this order on an underlayer wiring, a via hole pattern is formed in the insulating film structure, then a groove pattern is formed in the hard mask film, and a grove is formed in the insulating film structure using this as a mask. According to the prior art, the via side wall is oxidized equally severely in the both processes. The trench side wall is oxidized severely in the via first process according to the prior art, whereas, according to the present invention, the oxidation thereof is suppressed to such an extent that an almost non-oxidized state can be created.

### TECHNICAL FIELD

The present invention relates to a method of producing a multilayer interconnection structure having groove wiring and a method of producing such a multilayer interconnection structure.

### BACKGROUND ART

Recent super LSI devices require integration of more than several millions of elements within a several-millimeter square chip. It is therefore imperative for these devices to miniaturize and form the elements in a multilayer structure. It is particularly important for increasing the device operation speed to reduce the wiring resistance and interlayer capacitance.

In order to decrease the wiring resistance and interlayer capacitance, it is a common practice to use a film having a lower dielectric constant than a silicon oxide film as an interlayer insulating film while using copper as a wiring material. A Dual Damascene method is also used to decrease the wiring resistance. Using the Dual Damascene method, the number of processes including those for burying copper and those for mechanically and chemically polishing copper can be reduced substantially in comparison with a Single Damascene method. Further, the absence of a barrier film on the top of a via makes it possible to decrease the via resistance.

Thus, a via first process is characterized in that the number of exposures to oxygen plasma is great and a structure obtained by the process has a thick oxide layer.

### DISCLOSURE OF THE INVENTION

### Problems to be Solved by the Invention

According to the via first process described above, ashing is performed twice in the state in which an interlayer film is exposed. As a result, if a so-called low dielectric constant film having a dielectric constant lower than a silicon oxide film is used as a wiring interlayer film, the amount of carbon contained in the low dielectric constant film is reduced and hence the relative dielectric constant is increased (ashing damage). Further, if ashing is performed in the state in which misalignment has occurred during exposure of a wiring groove pattern, the low dielectric constant film will undergo more serious damages.

It is therefore an object of the present invention to provide a method of producing a multilayer interconnection having a low dielectric constant film used as a wiring interlayer film, in which ashing damage is reduced between wiring layers, and to provide multilayer interconnection having high reliability, reduced increase in the relative dielectric constant of a groove insulating film, and improved adhesion between a via insulating film and a barrier film.

### Means for Solving the Problems

The present invention provides a production method capable of etching a low dielectric constant film with less damage in Dual Damascene interconnection using a SiOCH low dielectric constant insulating film, and also provides a multilayer interconnection structure obtained by this method.

More specifically, the present invention provides a method of producing multilayer interconnection which includes stacking, on an underlayer wiring, a barrier insulating film, a via interlayer insulating film, a wiring interlayer insulating film, and a hard mask film sequentially in this order, forming a via hole pattern in the insulating film structure, then forming a groove pattern in the hard mask film, and forming a groove in the insulating film structure using this groove pattern as a mask.

The hard mask film is formed using a material having resistance against oxygen ashing, and may be formed of two or more layers, for example, formed by using a silicon oxide film as a lower layer and a silicon nitride film as an upper layer so that the upper hard mask layer is thin. Further, a stacked film with a metallic material, such as titanium, tantalum, tungsten or aluminum, an alloy thereof, or a compound thereof, may be used as the hard mask. A porous film, for example, having a lower relative dielectric constant than a silicon oxide film is used as the via and the wiring interlayer film. The wiring interlayer film is characterized by being a single-layer low dielectric constant film, or a stacked film including at least one type of low dielectric constant film such as a stacked film of different types of low dielectric constant films. When two or more layers are stacked, in the wiring interlayer film an upper-layer low dielectric constant film has a lower carbon/silicon ratio than that of a lower-layer low dielectric constant film. In the hard mask, the lower-layer hard mask has resistance against ashing and contains at least one or several selected from among silicon, nitrogen, and carbon. Further, the upper-layer hard mask is not limited to an inorganic film but also may be of a metal such as titanium, tantalum, tungsten, or aluminum, or an alloy or a compound thereof.

As a result, provided is a multilayer interconnection structure in which a side wall of a wiring groove insulating film is oxidized less than the inside thereof, while a side wall of a wiring insulating film directly above a via is oxidized, and in which a side wall of a via hole insulating film is oxidized more than the inside thereof.

### Effects of the Invention

The present invention provides a method of production a multilayer interconnection having a low dielectric constant film used as a wiring interlayer film, in which ashing damage is reduced between wiring layers, and provides highly reliable multilayer interconnection in which the increase in relative dielectric constant of a groove insulating film is reduced and adhesion between a via insulating film and a barrier film is high.

### BRIEF DESCRIPTION OF THE DRAWINGS

FIGS. 1(a), (b), (c), and (d) are diagrams showing a production method of multilayer interconnection using a via first process, as an example of conventional Dual Damascene processing;

FIGS. 2(a), (b), (c), and (d) are diagrams showing a production method of multilayer interconnection using a via first process, as an example of the conventional Dual Damascene processing;

FIG. 3 is a diagram illustrating a SiOCH etching technique having a high SiO₂ selection ratio;

FIG. 4 is a diagram illustrating an MPS etching technique having a high Aurora-ULK selection ratio;

FIGS. 5(a), (b), (c), and (d) show a production method of multilayer interconnection according to a first exemplary embodiment of the present invention;

FIGS. 6(a), (b), (c), and (d) show the production method of multilayer interconnection according to the first exemplary embodiment of the present invention;

FIGS. 7(a), (b), (c), and (d) show the production method of multilayer interconnection according to the first exemplary embodiment of the present invention;

FIGS. 8(a), (b), and (c) show other examples to which the production method of multilayer interconnection according to the first exemplary embodiment of the present invention is applied;

FIGS. 9(a) and (b) show comparison between the first exemplary embodiment of the present invention and a conventional process;

FIGS. 10(a), (b), (c), and (d) show a production method of multilayer interconnection according to a second exemplary embodiment of the present invention;

FIGS. 11(a), (b), (c), and (d) show the production method of multilayer interconnection according to the second exemplary embodiment of the present invention;

FIGS. 12(a), (b), and (c) show the production method of multilayer interconnection according to the second exemplary embodiment of the present invention;

FIGS. 13(a), (b), and (c) show the production method of multilayer interconnection according to the second exemplary embodiment of the present invention;

FIGS. 14(a), (b), (c), and (d) show a production method of multilayer interconnection according to a third exemplary embodiment of the present invention;

FIGS. 15(a), (b), (c), and (d) show the production method of multilayer interconnection according to the third exemplary embodiment of the present invention;

FIGS. 16(a), (b), and (c) show the production method of multilayer interconnection according to the third exemplary embodiment of the present invention;

FIGS. 17(a) and (b) show other example of the production method of the multilayer interconnection according to the third exemplary embodiment of the present invention; and

FIG. 18 shows a production method of multilayer interconnection according to a fourth exemplary embodiment of the present invention.

### LIST OF REFERENCE NUMERALS

1, 201, 301: Underlayer wiring
2: Cap film
3: Via interlayer film
4: Stopper film
5: Trench interlayer film
6: Hard mask
7, 9, 208, 212, 308, 312: Anti-reflection film
8: Resist for opening contact hole
8a: Resist pattern for opening contact hole
10, 213, 313: Resist for wiring groove
10a, 10b, 10c, 213a, 213b, 213c, 313a, 313b, 313c: Resist pattern for wiring groove
11, 214, 314: Copper wiring
12: Cu cap film
20, 21a, 21b, 230, 231: Oxidation modified layer
202, 215, 302, 315: Silicon carbon nitride film
203, 303: Aurora-ULK film
204, 206, 211, 306, 311, 605: Silicon oxide film
205, 304: MPS film
207, 307: Silicon nitride film
209, 309: Resist for via hole
209a, 309a: Resist pattern for via hole
210, 310: Organic film
220, 320: Liner
221, 321: Cu cap low dielectric constant film
305: Rigid SiOCH film
330, 331, 332: Oxidation modified layer
601: Silicon substrate
602: Isolation insulating film
603: MOSFET
604: Contact plug
606: First copper wiring
607: First via plug
608: Second copper wiring
609: Second via plug
610: Third copper wiring
613, 613a: Trench cap silicon carbon nitride film
614, 614a, 614b: Interlayer film
615, 615b: BD film
616: Barrier film
617: Copper
618: Modified layer

### BEST MODE FOR CARRYING OUT THE INVENTION

Before describing exemplary embodiments of the present invention, production methods of multilayer interconnection and multilayer interconnection structures according to the prior art will be described in order to facilitate the understanding of the present invention.

The prior art includes a so-called via first process.

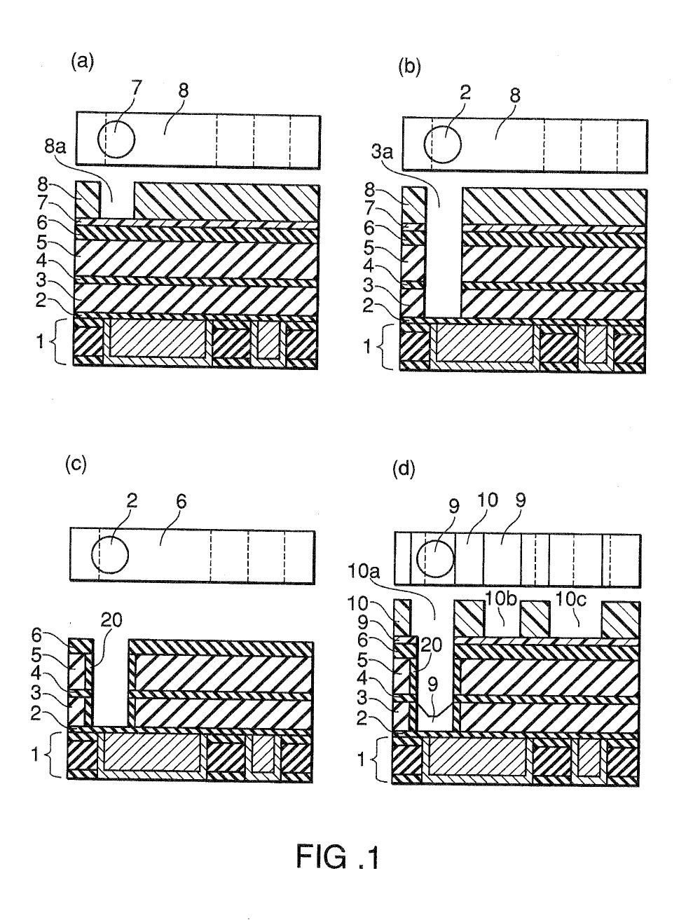

As shown in FIG. 1(a), a cap film 2 is formed on the top face of a lower interconnection structure 1. As described later, the cap film 2 serves as an etching stopper when etching a via interlayer film 3. The via interlayer film 3 is formed on the top face of the cap film 2. A stopper film 4 is further formed on the top face of the via interlayer film 3. This stopper film 4 serves as an etching stopper when etching a wiring interlayer film 5 as described later. The wiring interlayer film 5 is formed on the top face of the stopper film 4. Further, a hard mask 6 is formed on the top face of the wiring interlayer film 5. Subsequently, an anti-reflection film 7 and a photoresist 8 are formed on the top face of the hard mask 6, and, further, a contact hole opening resist pattern 8a is formed in the photoresist 8, using a photolithography technology.

Subsequently, as shown in FIG. 1(b), using a photoresist 8 having the contact hole opening pattern 8a formed therein as a mask, the anti-reflection film 7, the hard mask 6, the wiring interlayer film 5, the stopper film 4, and the via interlayer film 3 are sequentially etched, whereby a contact hole opening 3a is formed. The etching of the via interlayer film 3 is stopped at the cap film 2.

Next, as shown in FIG. 1(c), the resist 8 and the anti-reflection film 7 are peeled off by means of oxygen plasma. During this process, an oxide layer 20 is formed by the oxygen plasma on the side walls of the via interlayer film 3 and a wiring interlayer film 5s. Then, as shown in FIG. 1(d), an anti-reflection film 9 and a photoresist 10 are formed on the top face of the hard mask 6. This anti-reflection film protects the cap film 2 at the bottom of the contact hole. Further, wiring groove resist patterns 10a, 10b, and 10c are formed in the photoresist 10 by using a photolithography technology.

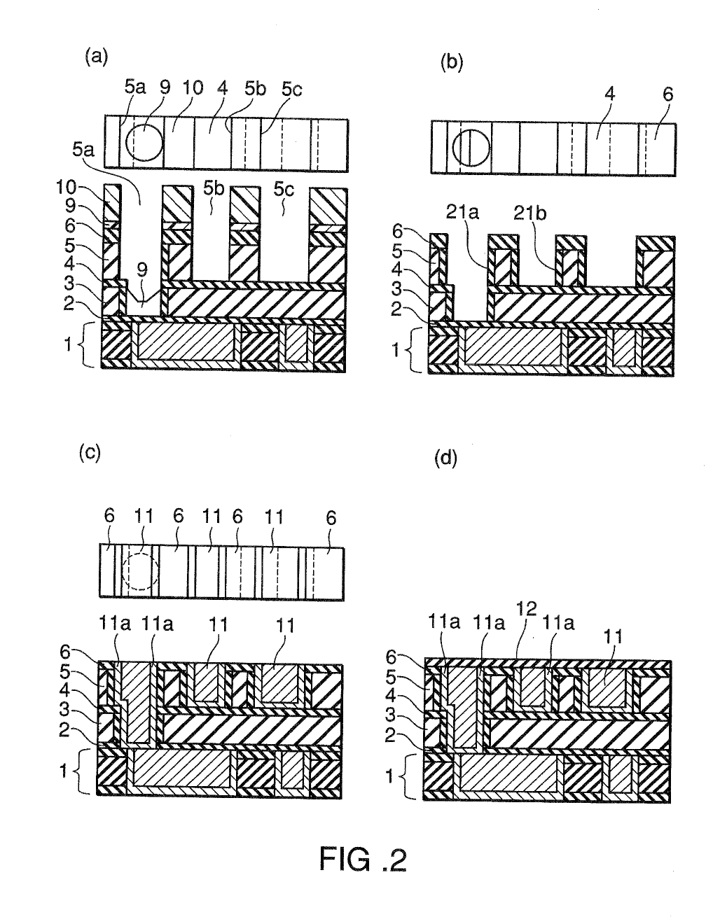

Subsequently, as shown in FIG. 2(a), the anti-reflection film 9, the hard mask 6, and the wiring interlayer film 5 under the photoresist patterns 10a, 10b, and 10c are sequentially etched to form wiring groove patterns 5a, 5b, and 5c.

Next, as shown in FIG. 2(b), the cap film 2 at the bottom of the contact hole is protected from etching plasma by the anti-reflection film. A Dual Damascene structure can be obtained by removing the cap film 2 after resist ashing. Like the peeling of the groove resist, oxygen plasma is used for ashing, and, likewise, both the via interlayer film 3 and the wiring interlayer film 5 are oxidized to form oxide layers 21a and 21b. In 21a, in particular, where the via side wall and the wiring side wall lie on a vertical straight line, a highly oxidized oxide layer is formed.

Subsequently, as shown in FIG. 2(c), the contact hole opening 3a and the wiring groove 5a are filled with a barrier film and copper, whereby copper wiring 11 is formed.

Further, as shown in FIG. 2(d), a Cu cap film 12 is formed.

A production method of multilayer interconnection according to the present invention will be described. In the production method of multilayer interconnection according to the present invention, an Aurora-ULK film produced by ASM which is a plasma CVD-SiOCH film is used as the via interlayer insulating film, and a MPS (Molecular Pore Stack) film which is a molecular pore film is used as the wiring interlayer insulating film. The MPS has a carbon/silicon ratio of 2.7, that is greater than 0.7 of the Auorora-ULK film. SiO₂ is used as the first hard mask, and SiN is used as the second hard mask.

According to the production method of multilayer interconnection of the present invention, a via is previously formed, then an organic film and a resist film are formed, a trench resist pattern is formed, the trench resist pattern is transferred to the hard mask, and then a trench is formed by using the hard mask. This method is characterized in that oxidation progresses on the via hole side wall since it is subjected to ashing occurring twice, while the side wall of the wiring interlayer film is not damaged by ashing since the trench formation is performed with the use of the hard mask.

A highly selective processing technique is required to realize the production method of the present invention. An etching selection ratio of five or more can be obtained between a SiOCH low dielectric constant insulating film and a silicon oxide film by performing etching with the use of mixture gas plasma in which oxygen gas is added to 40% or more nitrogen gas and 40% or more fluorocarbon gas.

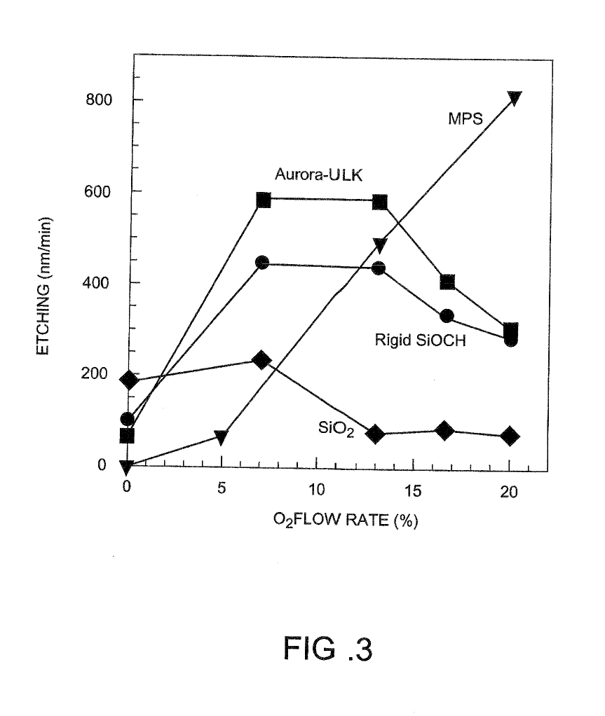

FIG. 3 is a diagram showing dependency of etching rate of SiOCH (rigid SiOCH, Aurora-ULK, MPS) and SiO₂ films on oxygen addition amount. The etching rate of the SiO₂ is decreased since the oxygen concentration at the surface thereof is increased by the increase of the oxygen addition amount. The etching rate of the SiOCH films, however, is increased until the oxygen addition amount reaches a certain extent since the carbon is made easier to remove from the surface thereof by the increase of the oxygen addition amount. Highly selective etching of SiOCH is made possible by using this oxygen addition amount for the etching.

Further, a selection ratio of three or more can be obtained by performing etching with the use of mixture gas plasma in which 15% or more oxygen gas and 5% or more but less than 20% fluorocarbon gas are diluted with nitrogen, while using SiOCH low dielectric constant films having different carbon/silicon ratios for the via and the wiring interlayer insulating film. Specifically, the formation of a Dual Damascene structure without a stopper is made possible by using Aurora-ULK having a low carbon/silicon ratio between the via layers and using MPS having a high carbon/silicon ratio between the wiring layers.

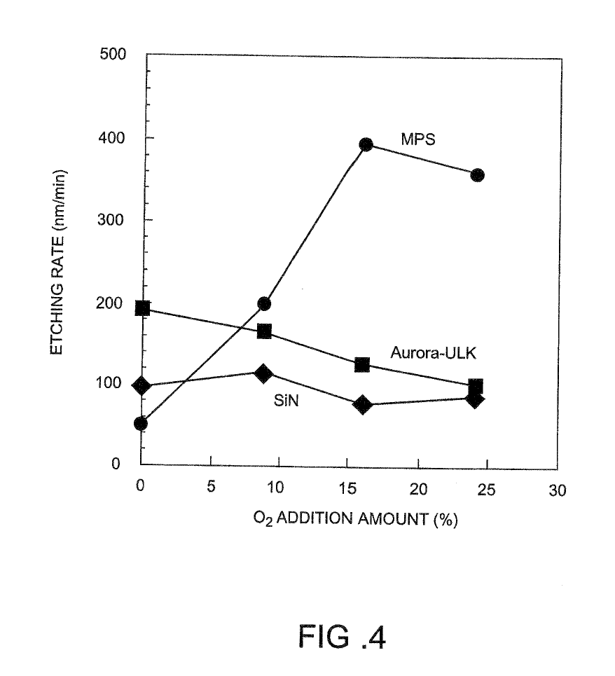

FIG. 4 is a diagram showing dependency of etching rate of MPS, Aurora-ULK, and SiN films on oxygen addition amount. The etching rate of the Aurora-ULK film, containing a high amount of Si, will become low if the fluorocarbon amount is low, while when the oxygen addition amount is increased, the etching rate thereof is decreased since the oxygen concentration at the surface becomes high. In contrast, the etching rate of the MPS film, having a high carbon content, is increased until the oxygen addition amount reaches a certain extent, since the carbon is made easier to remove from the surface when the oxygen addition amount is increased. The MPS can be etched highly selectively by using this oxygen addition amount for etching, and thus formation of a Dual Damascene structure without a stopper is made possible.

Further, the use of the above-mentioned two different mixture gas plasma conditions in combination makes it possible to perform processing to realize a desirably shaped structure for a wiring interlayer film having a low dielectric constant film and porous low dielectric constant film stacked, even if no stopper is provided.

Using the present invention, the via insulating film is oxidized sufficiently and hence the adhesion between the barrier film and the side wall of the via interlayer insulating film can be enhanced. Further, as a result of the sufficient oxidation, leakage between the vias can be prevented and hence the reliability can be improved. Since the groove insulating film is not ashed, multilayer interconnection having a low dielectric constant can be formed.

According to the present invention, multilayer interconnection having a low dielectric constant film used as a wiring interlayer film can be formed such that the trench side wall is not damaged by ashing, the adhesion and the leakage of the via interlayer film can be suppressed. Thus, multilayer interconnection having a low effective relative dielectric constant and high via reliability can be provided.

### EXEMPLARY EMBODIMENTS

Exemplary embodiments of the present invention will be described with reference to the drawings.

### Exemplary Embodiment 1

### Basic Structure−Half Via+DHM

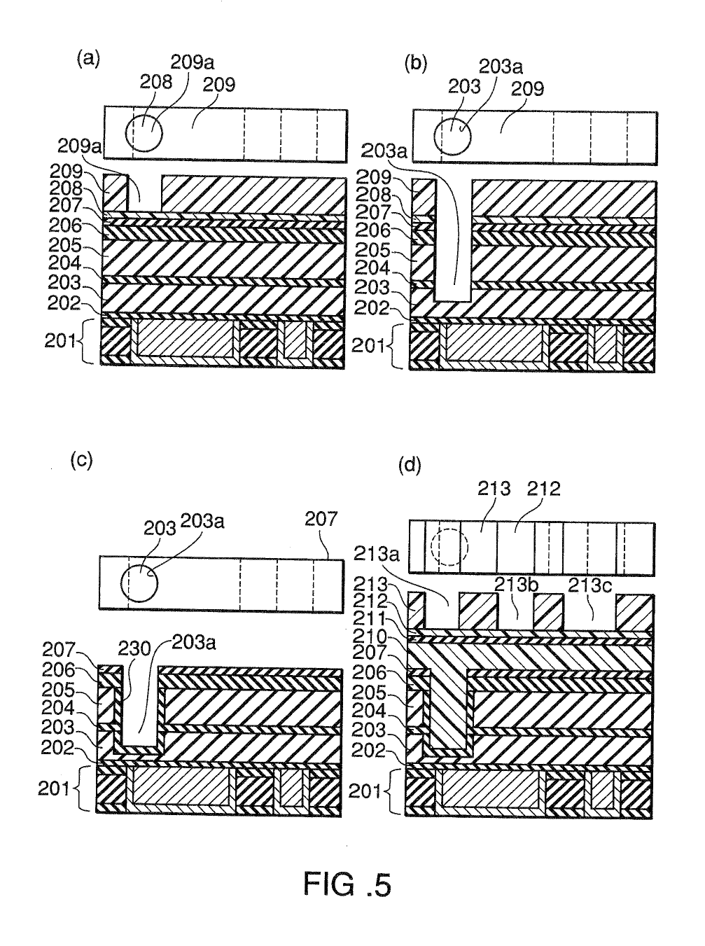

FIGS. 5 to 7 are main part plan views and cross-sectional views schematically showing a production process of a multilayer interconnection structure according to a first exemplary embodiment of the present invention. The first exemplary embodiment relates to formation of so-called Dual Damascene Cu interconnection in which a via and a trench are formed in an insulating film structure consisting of a silicon oxide film, a MPS film, a silicon oxide film stopper, and an Aurora-ULK. According to the first exemplary embodiment, Dual Damascene processing can be performed without damaging the side wall of the MPS film in the trench portion by forming a via to reach halfway of the Aurora-ULK film, then applying an organic material and resist, forming a trench resist pattern, and forming a groove by silicon nitride film/silicon oxide film hard mask processing.

First, as shown in FIG. 5(a), there are formed on an underlayer wiring 201, a silicon carbon nitride film 202 as a copper cap film, an Aurora-ULK film 203 as a via interlayer insulating film, a silicon oxide film 204 as an etching stopper, a MPS film 205 as a wiring interlayer insulating film, a silicon oxide film 206 as a lower-layer hard mask, and a silicon nitride film 207 as an upper-layer hard mask sequentially in this order by a plasma CVD method, for example. Then, an anti-reflection film 208 and a via resist 209 are applied in this order to form a via resist pattern 209a.

Then, as shown in FIG. 5(b), using the resist 209 formed with the via resist pattern 209a as a mask, the anti-reflection film 208, the silicon nitride film 207, the silicon oxide film 206, the MPS film 205, the silicon oxide film 204, and a part of the Aurora-ULK film 203 are etched in this order.

After that, as shown in FIG. 5(c), a via hole pattern 203a is formed by performing ashing, using oxygen plasma, for example. During this ashing, an oxide layer 230 is formed on the side walls of the Aurora-ULK film 203 and the MPS film 205 by the oxygen plasma. Then, an organic film 210 is applied on the silicon nitride film 207, and a silicon oxide film 211 is formed, for example, by a CVD method.

Next, as shown in FIG. 5(d), an anti-reflection film 212 and a trench resist 213 are applied in this order on the silicon oxide film 211, and trench resist patterns 213a, 213b, and 213c are formed.

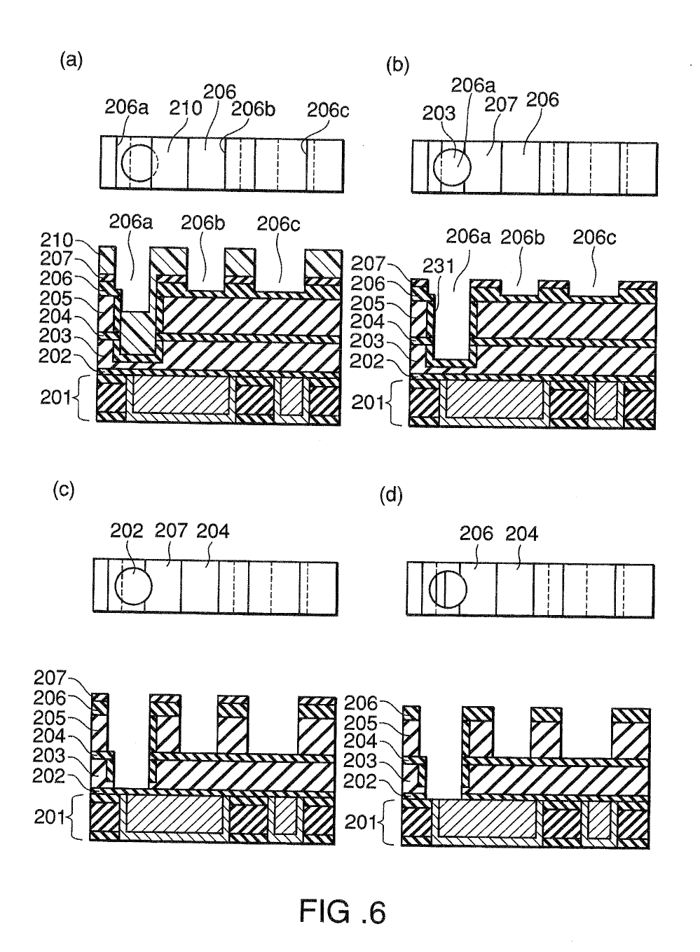

Subsequently, as shown in FIG. 6(a), using the resist 213 formed with the trench resist patterns 213a, 213b, and 213c as a mask, the anti-reflection film 212, the silicon oxide film 211, the organic film 210, the silicon nitride film 207, and a part of the silicon oxide film 206 are etched. The trench resist 213 and the anti-reflection film 212 disappear during the etching of the organic film 210, and the silicon oxide film 212 disappears during the etching of a part of the silicon oxide film 206. As a result, the organic film 210 becomes the uppermost layer after the etching process shown in FIG. 6(a).

Then, as shown in FIG. 6(b), the organic film 210 is ashed with oxygen plasma, for example, whereby trench groove hard mask patterns 206a, 206b, and 206c having the trench groove patterns transferred thereto can be formed. During this ashing, the MPS film 205 located under the trench groove hard mask patterns 206a, 206b, and 206c is not exposed to the ashing plasma and hence is not damaged. On the other hand, the previously formed via patterns are oxidized by being exposed to the oxygen plasma.

Further, as shown in FIG. 6(c), the remaining part of the silicon oxide film 206 and the MPS film 205 are etched by using the silicon nitride film 207 having the trench groove hard mask patterns 206a, 206b, and 206c formed therein as a mask, while the remaining part of the Aurora-ULK film 203 is etched by using the insulating film having the via hole pattern 203a formed therein as a mask. This etching can be performed without causing shape deterioration of the hard mask by etching the MPS with mixture gas plasma in which oxygen gas is added to 40% or more nitrogen gas and 40% or more fluorocarbon gas.

As shown in FIG. 6(d), the silicon nitride film hard mask 207 disappears during etching back of the copper cap film 202.

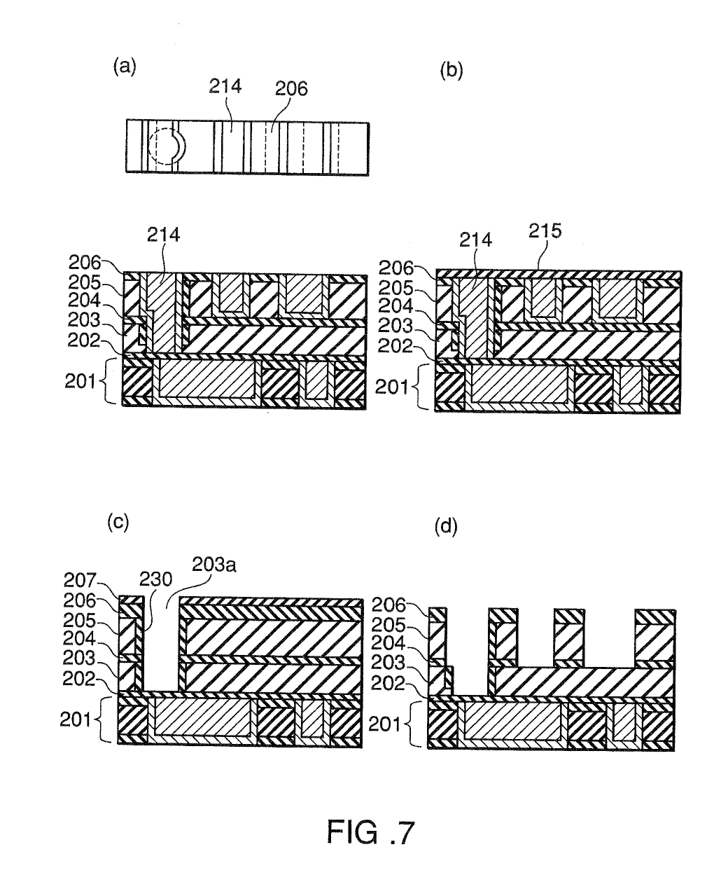

Then, as shown in FIG. 7(a), barrier Cu seed sputtering and Cu plating are performed, and Cu wiring 214 is formed by CMP.

Further, as shown in FIG. 7(b), a silicon carbon nitride film 215 is formed as a Cu cap film by CVD, for example. Multilayer interconnection can be formed by repeating this. The side wall of the Aurora-ULK film 203 is subjected twice to the oxygen ashing to be oxidized severely, resulting in improvement in adhesion of the barrier and improvement in reliability between the via layers. On the other hand, the side wall of the part of the MPS film 205 not located directly above the via is not subjected to the oxygen ashing and hence the relative dielectric constant thereof is kept low.

Although the above description of this exemplary embodiment has been made using an Aurora-ULK film as the via interlayer film, the material of the via interlayer film is not limited to Aurora-ULK, but CVD-SiOCH films such as other Aurora series products produced by ASM Japan, Orion produced by Tricon, BD/BD II (Black Diamond/Black Diamond II) produced by Applied Materials, and Coral produced by Novellus, or SiOCH films formed by applying a material such as porous SiLK produced by Dow-Chemical or NCS produced by Catalysts and Chemicals may be used. Further, SiOCH films formed by plasma polymerization as described in Japanese Laid-Open Patent Publication No. 2004-047873 (Document 1) also may be used. Although the above description has been made using a MPS film as the wiring interlayer insulating film, the same materials as mentioned in the above can be used instead. When taking package resistance into consideration, it is preferable to select a material having a higher density for the via interlayer insulating film than a material for the wiring interlayer insulating film.

Although the above description of the exemplary embodiment has been made using a silicon carbon nitride film as the Cu cap film, any other material may be used without any specific restriction as long as the material has Cu barrier property and is able to ensure a necessary etching selection ratio with respect to the low dielectric constant film. For example, a silicon carbide film and a silicon nitride film may be used. Further, an organic film formed by a plasma polymerization method, or an organic film containing siloxane such as divinyl-siloxane benzocyclobuten (DVS-BCB) may be used. Although the description above has been made using a silicon oxide film as the etching stopper film, any other material may be used without any specific restriction as long as the material is able to ensure a necessary etching selection ratio with respect to the low dielectric constant film, and a low dielectric constant film having SiOCH composition may be may be used, for example. Although in the description above the combination of SiN/SiO₂ is used as the hard mask, any other combination may be used without any specific restriction as long as it is able to ensure a necessary selection ratio. For example, combinations such as SiC/SiO₂, SiCN/SiO₂, SiO2/SiN, SiO₂/SiC, and SiO₂/SiCN, and other combinations that exhibit a high selection ratio with respect to a porous SiOCH film may be used. In addition, titanium, tantalum, tungsten, aluminum, or an alloy thereof, or an oxide or nitride thereof may be used for one or both of the hard masks. Further, a low dielectric constant film or a modified film thereof may be used as long as it has resistance against ashing.

Although the above-description of this exemplary embodiment has been made in terms of the method in which the via etching is conducted to about a half of the Aurora-ULK film, the via etching may be performed to remove the entire of the Aurora-ULK film as shown in FIG. 7(c). Further, the silicon oxide film stopper may be etched away when etching back the Cu cap film as shown in FIG. 7(d).

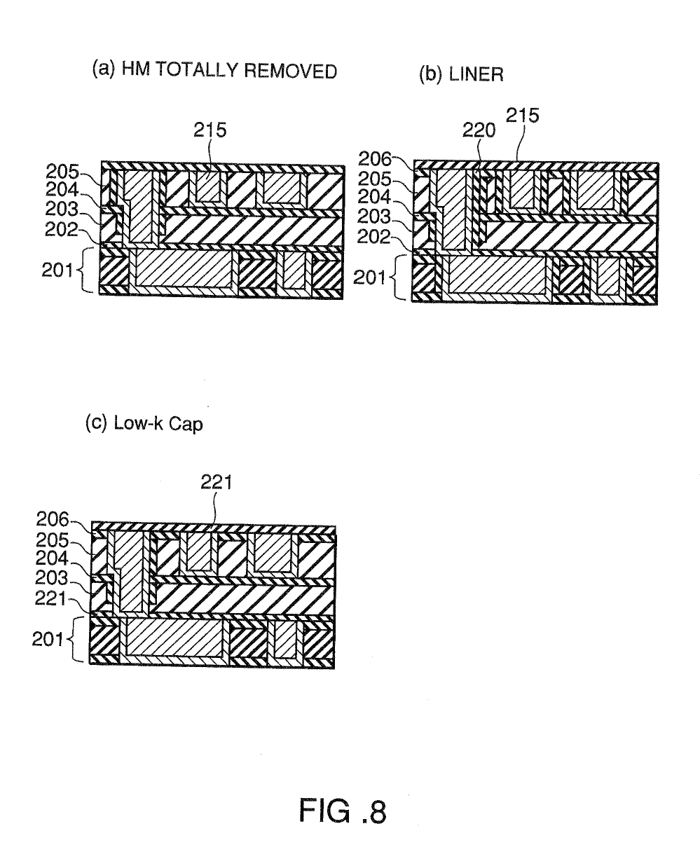

Structures as shown in FIG. 8 are conceivable as other examples to which this exemplary embodiment is applicable.

As shown in FIG. 8(a), the silicon oxide film on the low dielectric constant film may be totally removed by CMP.

As shown in FIG. 8(b), a liner 220 may be provided for protecting the side wall of the porous SiOCH film or controlling the side wall roughness. In this case, the liner may be provided by a silicon oxide film, a silicon nitride film, a silicon carbon nitride film, a silicon carbide film, a SiOCH film, an organic film formed by plasma polymerization, or a siloxane-containing organic film.

FIG. 8(c) shows an example in which a low dielectric constant film 221 is used as the Cu cap film. As described before, an organic film formed by a plasma polymerization method or an organic film containing siloxane, such as divinyl-siloxane benzocyclobuten (DVS-BCB), may be used.

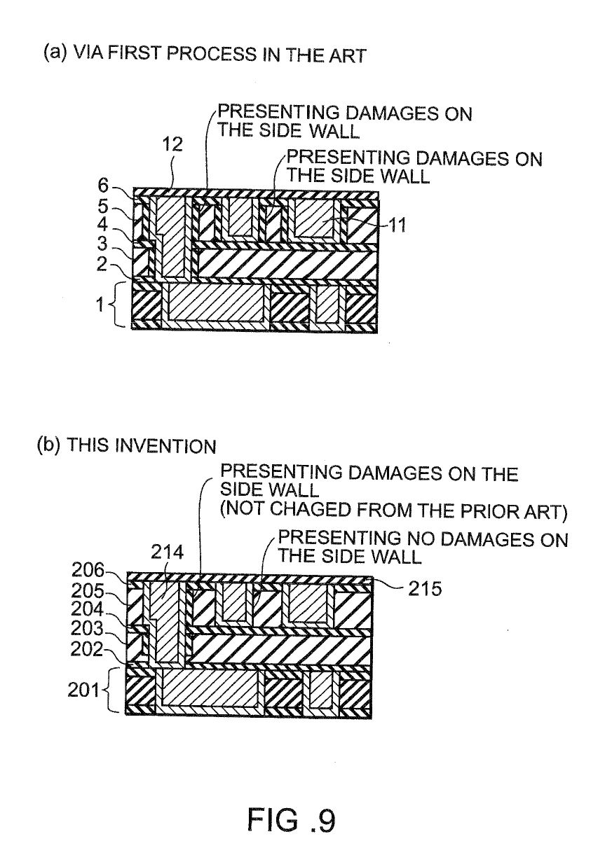

FIG. 9(a) and FIG. 9(b) are schematic cross-sectional views showing Dual Damascene interconnection structures formed by a conventional via first process and by the present invention, respectively. The via side walls are oxidized equally severely in both structures. In contrast, the trench side wall is oxidized severely according to the via first process shown in FIG. 9(a), while the oxidation is suppressed and an almost non-oxidized state can be created according to the present invention shown in FIG. 9(b). As a result, according to the present invention, the effective relative dielectric constant can be suppressed while ensuring the reliability of the vias.

### Exemplary Embodiment 2

### Half Via+DHM+Stopperless

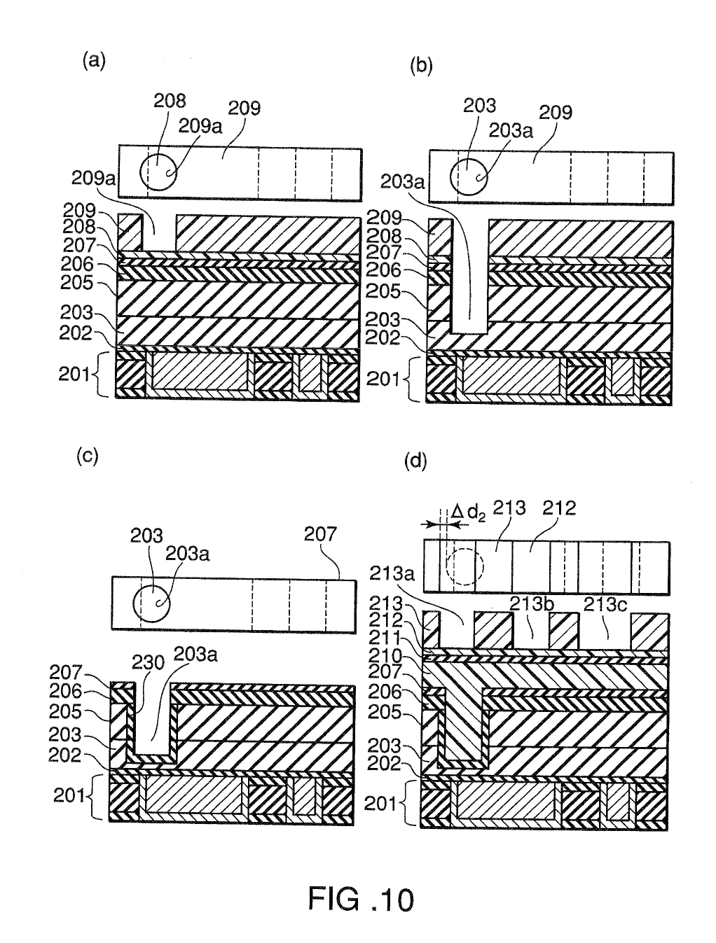

FIGS. 10 to 12 are main part plan views and cross-sectional views schematically showing a production process of a multilayer interconnection structure according to a second exemplary embodiment of the present invention.

The second exemplary embodiment relates to formation of so-called stopperless Dual Damascene Cu interconnection in which a via and a trench are formed in an insulating film structure consisting of a silicon oxide film, MPS, and Aurora-ULK, and in which the stopperless Dual Damascene structure can be obtained without causing damages to the side walls of the MPS film in the trench portion by applying an organic material and resist after forming a via to reach halfway of the Aurora-ULK film, forming a trench resist pattern, and forming a groove by a silicon nitride film/silicon oxide film hard mask process. This production method will be specifically described below.

First, as shown in FIG. 10(a), a silicon carbon nitride film 202 as a copper cap film, a Aurora-ULK film 203 as a via interlayer insulating film, a MPS film 205 as a wiring interlayer insulating film, a silicon oxide film 206 as a lower-layer hard mask, and a silicon nitride film 207 as an upper-layer hard mask are formed on underlayer wiring 201, sequentially in this order by a plasma CVD method, for example. Then, an anti-reflection film 208 and a via resist 209 are applied thereon in this order and a via resist pattern 209a is formed.

Then, as shown in FIG. 10(b), the anti-reflection film 208, the silicon nitride film 207, the silicon oxide film 206, the MPS film 205, and a part of the Aurora-ULK film 203 are etched in this order, using the resist 209 formed with the via resist pattern 209a as a mask.

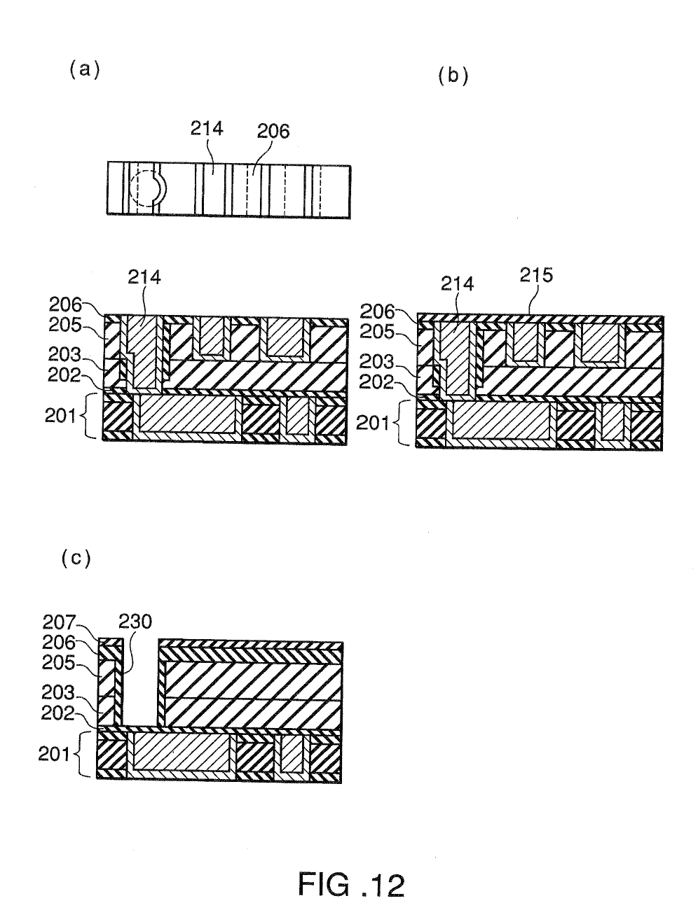

After that, as shown in FIG. 10(c), ashing is performed by using oxygen plasma, for example, whereby a via hole pattern 203a is formed. During this ashing, an oxide layer 230 is formed on the side walls of the Aurora-ULK film 203 and the MPS film 205 by the oxygen plasma. Although in the description here the etching is performed to a half of the Aurora-ULK film, the Aurora-ULK film may be totally etched away as shown in FIG. 12(c).

Then, as shown in FIG. 10(d), an organic film 210 is applied on the silicon nitride film 207 and a silicon oxide film 211 is formed by a CVD method, for example. An anti-reflection film 212 and a trench resist 213 are applied in this order on the silicon oxide film 211, and trench resist patterns 213a, 213b, and 213c are formed.

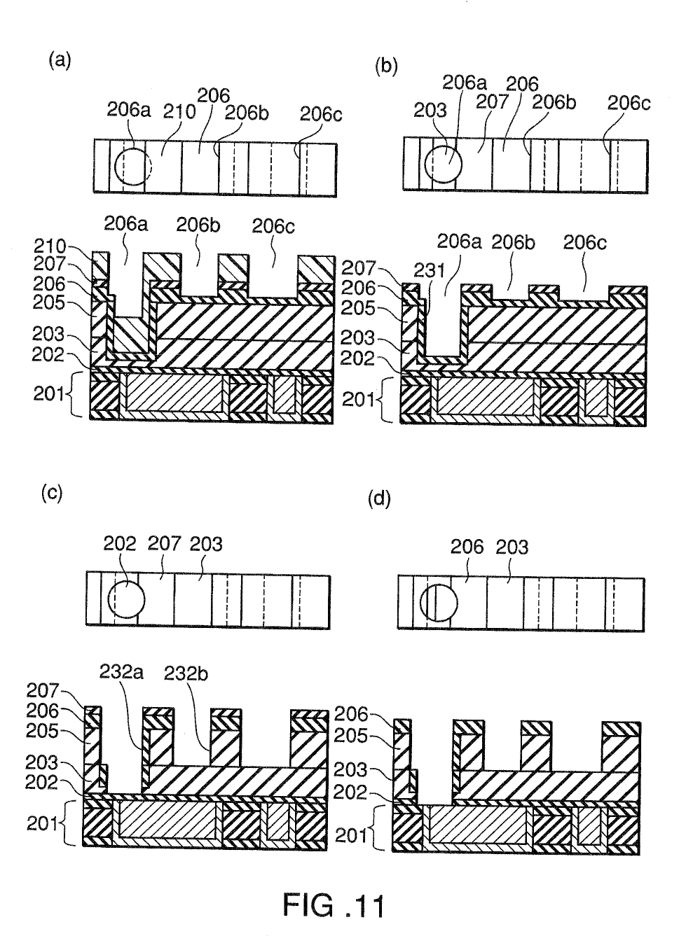

As shown in FIG. 11(a), using the resist 213 formed with the trench resist patterns 213a, 213b, and 213c as a mask, the anti-reflection film 212, the silicon oxide film 211, the organic film 210, the silicon nitride film 207, and a part of the silicon oxide film 206 are etched. The trench resist 213 and the anti-reflection film 212 disappear during the etching of the organic film 210, and the silicon oxide film 212 disappears during the etching of a part of the silicon oxide film 208. Accordingly, as shown in FIG. 11(a), the organic film 210 is located at the uppermost layer after the etching process.

Then, as shown in FIG. 11(b), the organic film 210 is ashed with oxygen plasma, for example, whereby trench groove hard mask patterns 206a, 206b, and 206c having the trench groove patterns transferred thereto are formed. During this ashing, the MPS film 205 located under the trench groove hard mask patterns 206a, 206b, and 206c is not exposed to the ashing plasma and hence is not damaged. On the other hand, the previously formed via patterns are exposed to the oxygen plasma and oxidized further.

Further, as shown in FIG. 11(c), the remaining part of the silicon oxide film 206 and the MPS film 205 are etched, using the silicon nitride film 207 formed with the trench groove hard mask patterns 206a, 206b, and 206c, while the remaining part of the Aurora-ULK film 203 is etched, using the insulating film formed with a via hole pattern 203a. The etching can be stopped at the Aurora-ULK film by etching the MPS with the use of mixture gas plasma in which 15% or more oxygen gas and 5% or more but less than 20% fluorocarbon gas are diluted with nitrogen.

Further, as shown in FIG. 11(d), the silicon nitride film hard mask 207 disappears when etching back the copper cap film 202.

Then, as shown in FIG. 12(a), barrier Cu seed sputtering and Cu plating are performed and a Cu wiring 214 is formed by CMP.

As shown in FIG. 12(b), an upper layer wiring M2 is aligned with a via V1, and hence the misalignment between M2 and V1 is limited to Δd2. Further, a silicon carbon nitride film 215 is formed as a Cu cap film by CVD, for example. Multilayer interconnection can be formed by repeating these steps. The side wall of the Aurora-ULK film 203 is subjected twice to the oxygen ashing and becomes a severely oxidized film, whereby the adhesion of the barrier is enhanced and the reliability between the via layers is improved. On the other hand, the side wall of the part of the MPS film 205 not located directly above the via is not subjected to the oxygen ashing and hence the relative dielectric constant thereof is kept low.

Although the above description of this exemplary embodiment has been made using an Aurora-ULK film as the via interlayer film, the material of the via interlayer film is not limited to Aurora-ULK, but CVD-SiOCH films, such as other Aurora series products produced by ASM Japan, Orion produced by Tricon, BD/BD II (Black Diamond/Black Diamond II) produced by Applied Materials, and Coral produced by Novellus, or SiOCH films formed by applying porous SiLK produced by Dow-Chemical or NCS produced by Catalysts and Chemicals may be used. Further, SiOCH films formed by plasma polymerization as described in Document 1 also may be used. Although the above description has been made using a MPS film as the wiring interlayer insulating film, the same materials as mentioned in the above can be used instead. In order to ensure a necessary etching selection ratio and to form a desirable Dual Damascene structure, it is preferable to use a wiring interlayer insulating film having a higher carbon/silicon ratio than that of the via interlayer insulating film. When taking package resistance into consideration, it is preferable to select a material having a higher density for the via interlayer insulating film than a material for the wiring interlayer insulating film.

Although the above description of the exemplary embodiment has been made using a silicon carbon nitride film as the Cu cap film, any other material may be used without any specific restriction as long as the material has Cu barrier property and is able to ensure a necessary etching selection ratio with respect to the low dielectric constant film. For example, a silicon carbide film and a silicon nitride film may be used. Further, an organic film formed by a plasma polymerization method, or an organic film containing siloxane such as divinyl-siloxane benzocyclobuten (DVS-BCB), may be used. Although in the description above the combination of SiN/SiO₂ is used as the hard mask, any other combination may be used without any specific restriction as long as it is able to ensure a necessary selection ratio. For example, combinations, such as SiC/SiO₂, SiCN/SiO₂, SiO2/SiN, SiO₂/SiC, and SiO₂/SiCN, and other combinations, that exhibit a high selection ratio with respect to a porous SiOCH film may be used. Further, titanium, tantalum, tungsten, aluminum, or an alloy thereof, or an oxide or nitride thereof may be used for one or both of the hard masks. Further, a low dielectric constant film or a modified film thereof may be used as long as it has resistance against ashing.

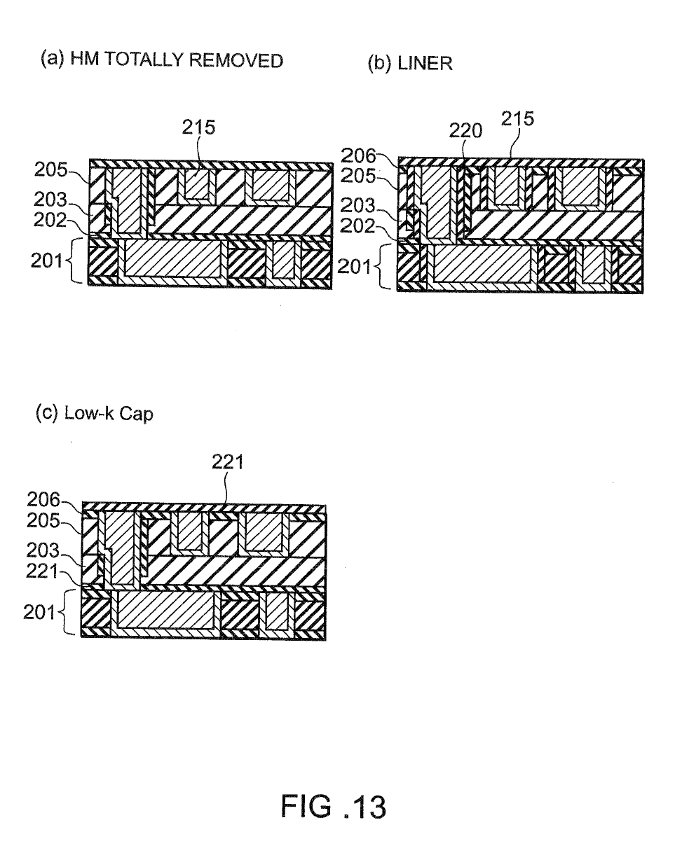

Structures as shown in FIG. 13 are conceivable as other examples to which this exemplary embodiment is applicable.

As shown in FIG. 13(a), the silicon oxide film on the low dielectric constant film may be totally removed by CMP.

Further, as shown in FIG. 13(b), a liner 220 may be provided for protecting the side wall of the porous SiOCH film or controlling the side wall roughness. In this case, the liner may be provided by a silicon oxide film, a silicon nitride film, a silicon carbon nitride film, a silicon carbide film, a SiOCH film, an organic film formed by plasma polymerization, or a siloxane-containing organic film.

Further, FIG. 13(c) shows an example in which a low dielectric constant film 103 is used as the Cu cap film. As described before, an organic film formed by a plasma polymerization method or an organic film containing siloxane such as divinyl-siloxane benzocyclobuten (DVS-BCB) may be used.

### Exemplary Embodiment 3

### Half Via+DHM+Stopperless+Low-k HM

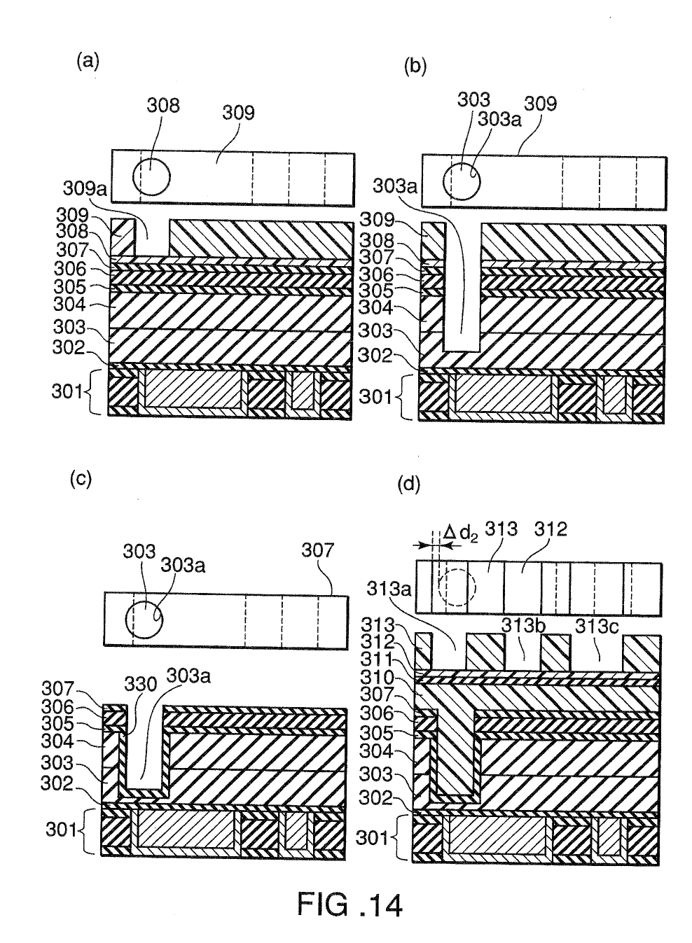

FIGS. 14 to 16 are main part plan views and cross-sectional views schematically showing a production process of a multilayer interconnection structure according to a third exemplary embodiment of the present invention.

The third exemplary embodiment relates to formation of Dual Damascene Cu interconnection having a so-called low dielectric constant film (low-k) hard mask/porous SiOCH/stopperless structure in which a via and a trench are formed in an insulating film structure composed of a silicon oxide film, rigid SiOCH, MPS, and Aurora-ULK, and in which the process is a via first process and a stopperless Dual Damascene structure can be obtained without damaging the side wall of the MPS film in the trench portion by applying an organic material and resist after forming a via to reach halfway of the Aurora-ULK film, forming a trench resist pattern, and forming a groove by a silicon nitride film/silicon oxide film hard mask process. Further, according to this exemplary embodiment, the dielectric constant of the hard mask can be decreased, and hence decrease of the effective dielectric constant can be expected.

First, as shown in FIG. 14(a), a silicon carbon nitride film 302 forming a copper cap film, an Aurora-ULK film 303 forming a via interlayer insulating film, a MPS film 304 forming a wiring interlayer insulating film, a rigid SiOCH film 305 forming a low-k hard mask, a silicon oxide film 306 as a lower-layer hard mask, and a silicon nitride film 307 as a lower-layer hard mask are formed sequentially in this order on an underlayer wiring 301 by a plasma CVD method, for example. An anti-reflection film 308 and a via resist 309 are applied thereon in this order and a via resist pattern 309a is formed.

Then, as shown in FIG. 14(b), the anti-reflection film 308, the silicon nitride film 307, the silicon oxide film 306, the rigid SiOCH film 305, the MPS film 304, and a part of the Aurora-ULK film 303 are etched in this order, using the resist 309 formed with the via resist pattern 309a as a mask.

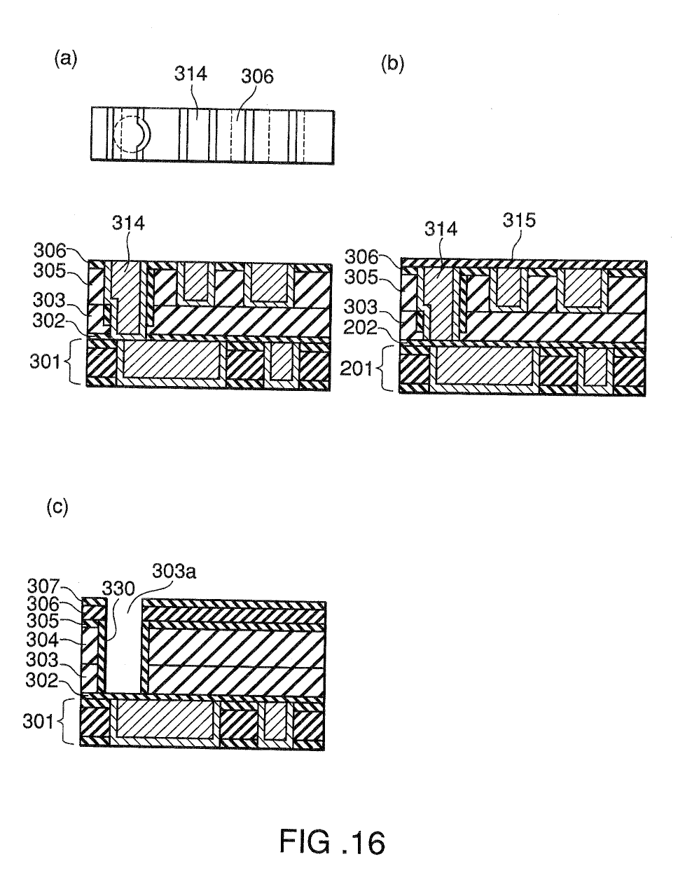

After that, as shown in FIG. 14(c), ashing is performed by using oxygen plasma, for example, whereby a via hole pattern 303a is formed. During this ahsing, an oxide layer 330 is formed on the side walls of the Aurora-ULK film 303 and the MPS film 304 by the oxygen plasma. Although the etching is performed halfway through the Aurora-ULK film 303 in this figure, the entire of the Aurora-ULK film 303 may be etched away as shown in FIG. 16(c).

After that, as shown in FIG. 14(d), an organic film 310 is applied on the silicon nitride film 307, and a silicon oxide film 311 is formed by a CVD method, for example. An anti-reflection film 312 and a trench resist 313 are applied in this order on the silicon oxide film 311, and trench resist patterns 313a, 313b, and 313c are formed.

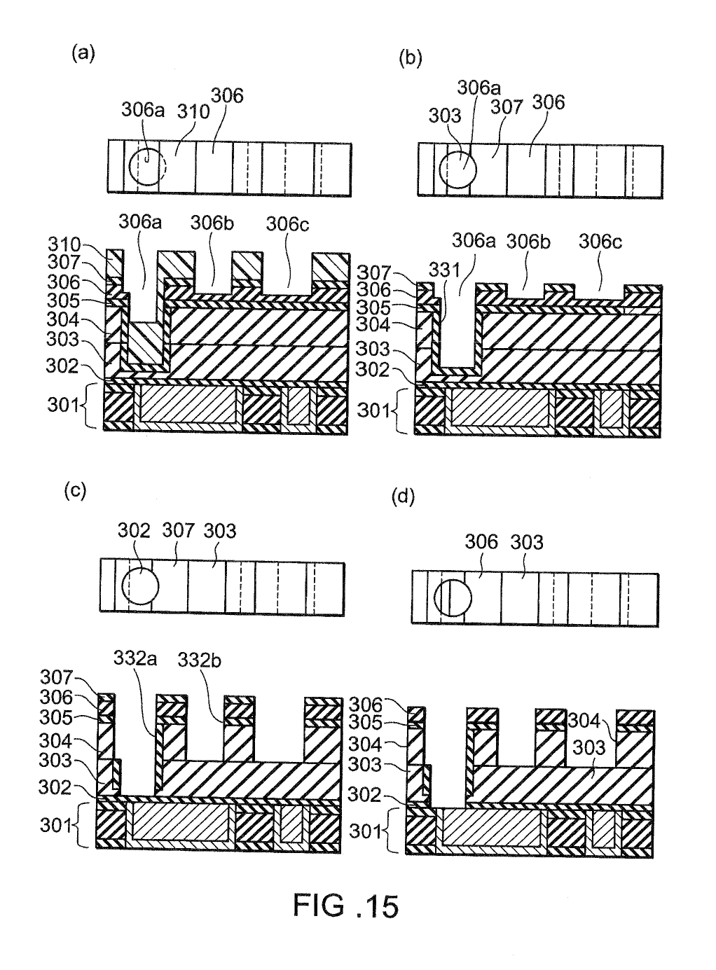

Next, as shown in FIG. 15(a), using the resist 313 formed with the trench resist patterns 313a, 313b, and 313c as a mask, the anti-reflection film 312, the silicon oxide film 311, the organic film 310, the silicon nitride film 307, and a part of the silicon oxide film 306 are etched. The trench resist 313 and the anti-reflection film 312 disappear during the etching of the organic film 310, and the silicon oxide film 311 disappears during the etching of a part of the silicon oxide film 306. Accordingly, the organic film 310 is located on the uppermost layer after the etching shown in FIG. 15(a).

Then, as shown in FIG. 15(b), the organic film 310 is ashed for example with oxygen plasma, whereby trench groove hard mask patterns 306a, 306b, and 306c having the trench groove patterns transferred thereto are formed. During this ashing, the rigid SiOCH film 305 located under the trench groove hard mask patterns 306a, 306b, and 306c is not exposed to the ashing plasma and hence is not damaged. Meanwhile, the previously formed via pattern is exposed to the oxygen plasma and is oxidized further.

Further, as shown in FIG. 15(c), the remaining part of the silicon oxide film 306, the rigid SiOCH film 305, and the MPS film 304 are etched by using the silicon nitride film 307 formed with the trench groove hard mask patterns 306a, 306b, and 306c as a mask, while the remaining part of the Aurora-ULK film 303 is etched by using the insulating film formed with the via hole pattern 303a as a mask. In this process, the rigid SiOCH is first etched with the use of mixture gas plasma in which oxygen gas is added to 40% or more nitrogen gas and 40% or more fluorocarbon gas. Since the selection ratio with respect to SiO₂ is high under this condition, the processing can be performed without causing dimensional error or shape anomaly in the hard mask.

Further, as shown in FIG. 15(d), the etching can be stopped at the Aurora-ULK film 303 by etching the MPS with the use of mixture gas plasma in which 15% or more oxygen gas and 5% or more but less than 20% fluorocarbon gas are diluted with nitrogen. Further, the silicon nitride film hard mask 307 disappears during etching back of the copper cap film 302.

After that, as shown in FIG. 16(a), barrier Cu seed sputtering and Cu plating are performed and Cu wiring 314 is formed by CMP. The entire of the SiO₂ hard mask is polished off, whereby only the low dielectric constant film is left between the wiring layers. Therefore, decrease of the dielectric constant can be expected. Further, according to this exemplary embodiment, no ashing damage occurs in the rigid SiOCH film and hence a sufficient CMP resistance can be ensured.

Further, as shown in FIG. 16(b), a silicon carbon nitride film 315 is formed as a Cu cap film by CVD, for example. Multilayer interconnection can be formed by repeating these steps. The side wall of the Aurora-ULK film 303 is subjected twice to the oxygen ashing and hence is oxidized severely, whereby the adhesion of the barrier is enhanced and the reliability between the via layers is improved. On the other hand, the side wall of the part of the MPS film 304 not located directly above the via is not subjected to the oxygen ashing and hence the relative dielectric constant thereof is kept low.

Although the above description of this exemplary embodiment has been made using an Aurora-ULK film as the via interlayer film, the material of the via interlayer film is not limited to Aurora-ULK, but CVD-SiOCH films, such as other Aurora series products produced by ASM Japan, Orion produced by Tricon, BD/BD II (Black Diamond/Black Diamond II) produced by Applied Materials, and Coral produced by Novellus, or SiOCH films formed by applying porous SiLK produced by Dow-Chemical or NCS produced by Catalysts and Chemicals, may be used.

Further, SiOCH films formed by plasma polymerization as described in Document 1 also may be used. Although the above description has been made using a MPS film as the wiring interlayer insulating film, the same materials as mentioned in the above can be used instead. In order to ensure a necessary etching selection ratio and to form a desirable Dual Damascene structure, it is preferable to use a wiring interlayer insulating film having a higher carbon/silicon ratio than that of the via interlayer insulating film. When taking package resistance into consideration, it is preferable to select a material having a higher density for the via interlayer insulating film than a material for the wiring interlayer insulating film. Further, although a rigid SiOCH film is used as the low-k hard mask in the above description, any of the low dielectric constant films as described above may be used without any restriction as long as it is a low-k film having resistance against CMP.

Although the above description of the exemplary embodiment has been made using a silicon carbon nitride film as the Cu cap film, any other material may be used without any specific restriction as long as the material has Cu barrier property and is able to ensure a necessary etching selection ratio with respect to a low dielectric constant film. For example, a silicon carbide film and a silicon nitride film may be used. Further, an organic film formed by a plasma polymerization method, or an organic film containing siloxane, such as divinyl-siloxane benzocyclobuten (DVS-BCB), may be used. Although in the description above the combination of SiN/SiO₂ is used as the hard mask, any other combination may be used without any specific restriction as long as it is able to ensure a necessary selection ratio. For example, combinations such as SiC/SiO₂, SiCN/SiO₂, SiO2/SiN, SiO₂/SiC, and SiO₂/SiCN, and other combinations that exhibit a high selection ratio with respect to a porous SiOCH film may be used. Further, titanium, tantalum, tungsten, aluminum, or an alloy thereof, or an oxide or nitride thereof may be used for one or both of the hard masks. Further, a low dielectric constant film or a modified film thereof may be used as long as it has resistance against ashing.

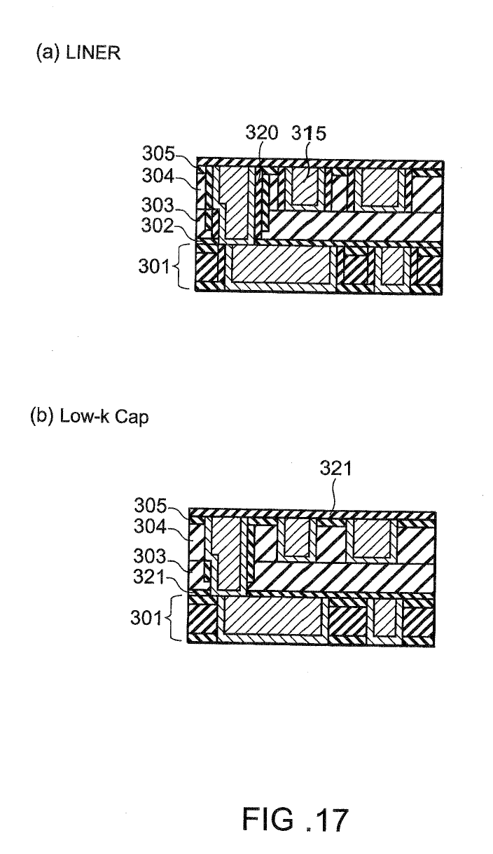

Structures as shown in FIG. 17 are conceivable as other examples to which this exemplary embodiment is applicable. As shown in FIG. 17(a), a liner 320 may be provided for protecting the side wall of the porous SiOCH film or controlling the side wall roughness. In this case, the liner may be provided by a silicon oxide film, a silicon nitride film, a silicon carbon nitride film, a silicon carbide film, a SiOCH film, an organic film formed by plasma polymerization, a siloxane-containing organic film, or the like.

### Exemplary Embodiment 4

### Multilayer Structure

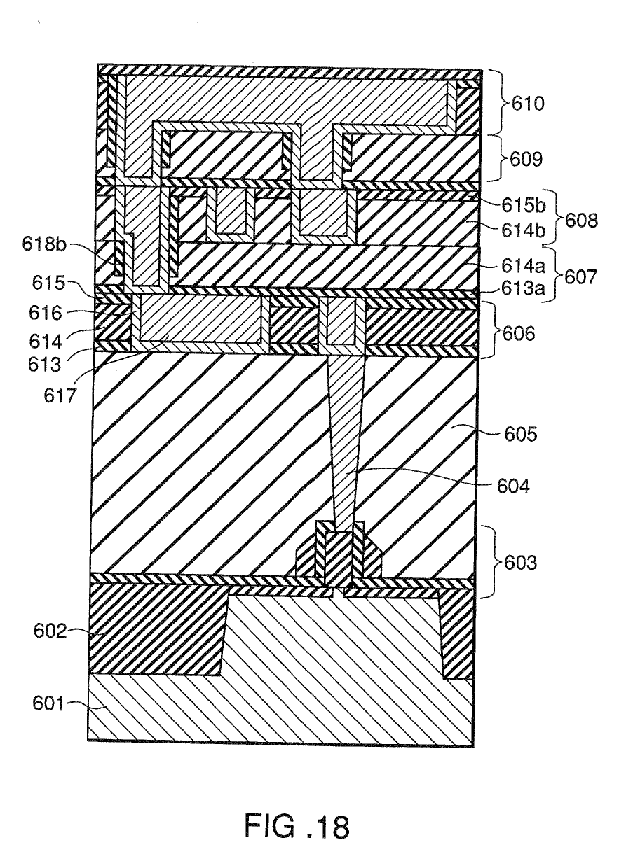

FIG. 18 shows an exemplary embodiment in which copper multilayer interconnection is formed in a carbon-containing low dielectric constant insulating film formed on a MOSFET 603 separated by an element separation oxide film 602 on a silicon substrate 601. Characteristics of this structure will be described below. According to this exemplary embodiment as well, a Dual Damascene interconnection structure can be obtained in which a side wall of a via interlayer film is oxidized while a side wall of a trench interlayer film located not directly above a via is not oxidized by using a combination of a via first resist process and a hard mask for formation of the Dual Damascene structure. Although the above description of this exemplary embodiment has been made using an Aurora-ULK film as the via interlayer film, the material of the via interlayer film is not limited to Aurora-ULK, but CVD-SiOCH films such as other Aurora series products produced by ASM Japan, Orion produced by Tricon, BD/BD II (Black Diamond/Black Diamond II) produced by Applied Materials, and Coral produced by Novellus, or SiOCH films formed by applying porous SiLK produced by Dow-Chemical or NCS produced by Catalysts and Chemicals may be used. Further, SiOCH films formed by plasma polymerization as described in Japanese Laid-Open Patent Publication No. 2004-047873 also may be used.

A silicon oxide film 605 having a W contact plug 604 is formed on the MOSFET 603, and a 30 nm thick silicon carbon nitride film 613 is formed on the silicon oxide film 605, as an etch stop film of a wiring groove corresponding to a first-layer copper wiring 606. A 110 nm thick MPS film 614 and a 30 nm thick BD film 615 as a hard mask thereof are formed on this silicon carbon nitride film. The first-layer copper wiring has a structure in which a wiring groove passing through a stacked insulating film consisting of the BD film 615, the MPS film 614 and the silicon carbon nitride film 613 is filled with a Cu film 617 covered with a barrier film 616 consisting of Ta (10 nm) and TaN (5 nm). This first Cu wiring layer 606 is connected to the W contact plug 604.

A 30 nm thick silicon carbon nitride film 613a is formed as a via etch-stop layer on the first Cu wiring layer 606. Further, a 130 nm thick Aurora-ULK film 614a is formed thereon. The Aurora-ULK film 614a may be flattened by CMP or the like. A 130 nm thick MPS film 614b and a 30 nm thick BD film 615b as a hard mask thereof are formed on the Aurora-ULK film 614a. This stacked insulating film is formed with a second Cu wiring 608 in which a wiring groove passing through the BD film 615b and the MPS film 614b is filled with a Cu film. A first Cu via plug 607 is formed to extend from the bottom of this second copper wiring 608, passing through the Aurora-ULK film 614a and the silicon carbon nitride film 613a, and is connected to the first Cu wiring layer 606. The side wall of the Aurora-ULK film 614a has an oxide layer 618b formed by two ashing steps, and the side wall of the MPS film 614b also has an oxide layer at its region aligned vertically with the via side walls. The presence of the oxide layer improves the adhesion with a barrier material and reduces the via leakage.

A third Cu wiring layer 610 and a Cu via plug 609 connecting the third and second layers also can be formed into the same structure as that of the second wiring layer 608 and the via plug 607, and multilayer interconnection can be obtained by stacking these structures.

### INDUSTRIAL APPLICABILITY

As described above, the production methods of multilayer interconnection according to the present invention are applicable to production of semiconductor devices and interconnection them.

1. A method of producing a Dual Damascene multilayer interconnection formed on a semiconductor substrate, the method comprising the steps of:
forming a via hole pattern in an insulating film structure having a barrier insulating film, a via interlayer insulating film, a wiring interlayer insulating film, and a hard mask film stacked in this order on an underlay er wiring, by the use of a photoresist and dry etching, such that the via hole pattern passes through at least the hard mask film and the wiring interlayer insulating film and reaches the via interlayer insulating film;
removing the photoresist by ashing processing using oxygen plasma;
forming a groove pattern of photoresist;
forming a groove pattern in the hard mask by using the photoresist as a mask;
removing the photoresist by ashing processing using oxygen plasma; and
transferring the groove pattern in the hard mask to the wiring interlayer insulating film by dry etching.

2. The method according to claim 1, wherein the wiring interlayer insulating film is an insulating film containing at least silicon and carbon.

3. The method according to claim 1, wherein a composition of the hard mask film is not changed by being exposed to oxygen plasma.

4. The method according to claim 3, wherein at least a part of the hard mask film is a SiO₂ film.

5. The method according to claim 1, wherein the hard mask film comprises at least two stacked film layers.

6. The method according to claim 5, wherein the lower hard mask film layer has a thickness greater than that of the upper hard mask film layer in the two hard mask film layers.

7. The method according to claim 1, wherein the hard mask film is formed by stacked films including a lower SiO₂ film and an upper SiN film.

8. The method according to claim 3, wherein at least a part of the hard mask film has a film formed of at least one or more types of materials selected from the group consisting of titanium, tantalum, tungsten, aluminum, alloys thereof, nitrides thereof, and oxides thereof.

9. The method according to claim 1, wherein an etching stopper film of SiO₂ is interposed between the via interlayer insulating film and the wiring interlayer insulating film.

10. The method according to claim 1, wherein the via interlayer insulating film has a carbon/silicon ratio lower than that of the wiring interlayer insulating film.

11. The method according to claim 1, comprising the steps of:
sequentially forming, on a underlayer wiring, a barrier insulating film of SiCN, a via interlayer insulating film of SiOCH, a wiring interlayer insulating film of porous SiOCH, and a hard mask film at least partially for med of a SiO₂ to form an insulating film structure;
forming a via hole resist pattern on the hard mask film and forming a via hole at least passing through the hard mask film and the wiring interlayer insulating film by dry etching;
removing the via hole resist pattern by oxygen plasma ashing;
forming a wiring groove resist pattern on the via hole, and then transferring the wiring groove resist pattern to the hard mask film by dry etching;
removing the wiring groove resist by oxygen plasma ashing; and
forming a groove pattern in the insulating film structure, using the wiring groove pattern transferred to the hard mask as a mask.

12. The method according to claim 11, wherein the hard mask film is for med by stacked films including a lower SiO₂ film and an upper SiN film.

13. A multilayer interconnection structure formed on a semiconductor substrate or a semiconductor layer in a state electrically connected to at least one circuit element formed on the semiconductor substrate or the semiconductor layer, and formed by stacking plural unit interconnection structures, each of the plural unit interconnection structures having a wiring and a via hole plug formed by filling, with a metal, a wiring groove formed in a wiring interlayer insulating film and a via hole formed in a via interlayer insulating film, respectively, wherein:
at least the wiring interlayer insulating film is a film containing at least carbon and silicon, and a side wall of the wiring interlayer insulating film of the wiring not located directly above the via hole plug has a lower film density that that of a side wall of the wiring interlayer insulating film located directly above the via hole plug.

14. A multilayer interconnection structure formed on a semiconductor substrate or a semiconductor layer in a state electrically connected to at least one circuit element formed on the semiconductor substrate or the semiconductor layer, and formed by stacking plural unit interconnection structures, each of the plural unit interconnection structures having a wiring and a via hole plug formed by filling, with a metal, a wiring groove formed in a wiring interlayer insulating film and a via hole formed in a via interlayer insulating film, respectively, wherein:
at least the wiring interlayer insulating film is a film containing at least carbon and silicon, and at least either the relative dielectric constant or the silicon/carbon ratio of the side wall of the wiring interlayer insulating film of the wiring not located directly above the via hole plug is lower than that of the side wall of the wiring interlayer insulating film located directly above the via hole plug.

15. The multilayer interconnection structure according to claim 13, wherein the via interlayer insulating film is a film containing at least carbon and silicon, and at least any of the relative dielectric constant, density, and silicon/carbon ratio of the inside of the via interlayer insulating film not in contact with the via hole plug is lower than that of the side wall of the via interlayer insulating film in contact with the via hole plug.
